(19) United States
(12) Patent Application Publication
(10) Pub. No.: US 2012/0138754 A1
(43) Pub. Date: Jun. 7, 2012

(54) Universal Frame For Flat Panel Displays

(76) Inventor: Seong Wong Lim, Kunshan (CN)

(21) Appl. No.: 13/054,571

(22) PCT Filed: Dec. 2, 2009
(86) PCT No.: PCT/CN2009/075268

§ 371 Date: Jan. 18, 2011

(30) Foreign Application Priority Data
May 12, 2009 (CN) 200920045225.3

(51) Int. Cl. H05K 7/00; F16L 3/08

(52) U.S. Cl. 248/74.1; 248/226.11; 248/231.71; 248/65

(57) ABSTRACT

The present invention provides a universal flat panel display frame which includes a supporting arm system, a universal head system and a fixing pedestal system. The universal flat panel display frame applies a translation mechanism with dual connecting rod supported by a spring force, and a crosshead universal head system, so as to allow the flat panel display installed thereon to be adjusted and fixed at a desired position and a desired angle at will. Only one person could activate the flat panel display by hand, and the height, front/back incline angle and right/left incline angle of the flat panel display can be adjusted at random just by applying a little force. Therefore, the present invention is convenient for a user to adjust the flat panel display at a desired position, or to rotate the flat panel display at a desired angle to show the screen to other people.

### BACKGROUND OF THE PRESENT INVENTION

1. Field of Invention

The present invention relates to a frame for flat panel displays, and more particularly to a frame which allows the flat panel display installed thereon to adjust its incline angle and distance to a user at random.

2. Description of Related Arts

At present, the flat panel display has been widely using as computer display device due to its light weight, thin screen and beautiful appearance. Generally, the flat panel display is installed on a fixed pedestal which is directly sit on desktop and allows the flat panel display to adjust its frontal incline angle. Therefore, the weakness of the fixed pedestal is also obvious. At first, the fixed pedestal has occupied valuable area of the desktop. Secondly, the flat panel display installed on the fixed pedestal is not easy to be moved, that is, it is hard to adjust its incline angle or to rotate the flat panel display at a larger angle for showing its screen to other people. Thus, the fixed pedestal is not convenient for the flat panel display to adjust its position.

### SUMMARY OF THE PRESENT INVENTION

A main object of the present invention is to provide a universal flat panel display frame which can adjust and fix the flat panel display at desired position and desired angle conveniently.

Accordingly, in order to accomplish the above objects, the present invention provides a universal flat panel display frame comprising a supporting arm system, a universal head system and a fixing pedestal system,

wherein taking the using direction of the flat panel display as reference, the fixing pedestal system comprises a supporter, a column, a U-plate, a tightening bolt, a tightening cover, a locating sleeve and a rotating tapered sleeve, wherein the column is fixed on the supporter, the U-plate clamps an edge of an desktop, and the supporter is fixed on the U-plate, wherein the U-plate has an internal thread hole provided in a bottom thereof, having threads engaged with threads of the tightening bolt, wherein a top threaded end of the tightening bolt is screwed through the internal thread hole which provided in the bottom of the U-plate, and the tightening cover 35 is fixed on the top threaded end of the tightening bolt, while a top surface of the tightening cover is pressed upwardly against a lower surface of the edge of the desktop tightly;

wherein the supporting arm system comprises a supporting arm, a supporting base, and a connecting head, wherein the locating sleeve is sleeved on the column, which is fixed by a screw when adjusted to a desired height on the column, wherein the rotating tapered sleeve is sleeved on the column coaxially with the locating sleeve, and a bottom of the rotating tapered sleeve is pressed against a top of the locating sleeve, wherein the supporting base is fixedly sleeved on the rotating sleeved, and hinged with one end of the supporting arm, wherein due to the special connection between the supporting arm system and the fixing pedestal system, the supporting arm system is allowed to rotate 360 degree around the column and adjust for height within an entire length of the column, that is, the flat panel display fixed on the supporter is allowed to rotate 360 degree around the column and adjust height within an entire length of the column,

wherein another end of the supporting arm is hinged with the connecting head, wherein the connecting head has a hollow cylinder in vertical direction, and the universal head system is rotatably connected to the hollow cylinder of the connecting head, wherein the supporting arm system further comprises two translation rods symmetrically provided at left and right sides of the supporting arm, wherein two ends of each translation rod are respectively hinged with the supporting base and the connecting head, therefore, the supporting arm and the translation connecting rods between the supporting base and the connecting head constitute two parallel parallelograms so as to form a translation mechanism with dual connecting rod, whereby, whether the connecting head is moved up or down, an axial lead of its hollow cylinder always parallels to an axial lead of the supporting base, also, because the supporting base is sleeved on the column of the fixing pedestal system, while the column is perpendicular to the desktop, and thus the axial lead of its hollow cylinder is always perpendicular to the desktop, that is to say, whether the connecting head is moved up or down, the axial lead of its hollow cylinder is always perpendicular to the desktop.

Furthermore, taking the using direction of the flat panel display as reference, the supporting arm system comprises a spring provided inside the supporting arm, wherein a fixed end of the spring is mounted on a front portion of the supporting arm, and a free end of the spring is fixed on a sliding spring base; two connecting bars, wherein one end of each connecting bar is hinged with the supporting base, and another end of each connecting bar hinged with the sliding spring base by a cylinder pin; a roller, with a diameter larger than the width of the sliding spring base, sleeved on the cylinder pin for helping the sliding spring base to slide, wherein the supporting base, the connecting bars and the supporting arm construct a linkage mechanism, in order to avoid the supporting arm moving down under a moment of force generated by its own gravity and the gravity of the flat panel display. When the connecting head moves down to cause a larger angle between the supporting arm and the column, a gravity center of the supporting arm and the flat panel display shifts outwards, that is, an distance between the force point and the supporting point is increased, the moment of force become larger. Meanwhile, the downward movement of the supporting arm makes the roller, mounted on the cylinder pin which connects the sliding spring base to the connecting bars, pressed down, also, due to the one end of the connecting bar hinging with the supporting base, the connecting bar can only push the sliding spring base to move toward the compression direction of the spring, and with movement of the sliding spring base, an elastic force of the spring become larger, therefore, a countermoment of the elastic force is enough to balance the moment of force generated by its own gravity and the gravity of the flat panel display, so as to keep the flat panel display still in balance. When the supporting arm is moved in a horizontal position, the distance between the flat panel display and a user is smallest. Continuing to move the supporting arm down, under a push action of the connecting bars on the spring, the spring is further compressed to a status that the connecting points between the supporting base and the supporting arm, the connecting points between the connecting bars and the supporting base and the connecting points between the connecting bars and the sliding spring base are in a line, then the linkage mechanism constructed by the supporting base, the connecting bars, and the supporting arm is in a dead-point position, and the elastic force of the spring reaches to maximum value at this position.

Furthermore, the supporting arm system comprises two locating loops respectively sleeved on two connecting points between the supporting base and the connecting bars for forming a lock mechanism, wherein when the linkage mechanism passes its dead-point position, one side of the supporting arm is blocked by the locating loops so as to avoid the flat panel display is elevated by the excessive elastic force of the spring 15. Concretely speaking, when the supporting arm is moved slightly down after the linkage mechanism reaching its dead-point position, the linkage mechanism will pass its dead-point position, then the side of the supporting arm is blocked by the locating loops for avoiding further falling, that is, the supporting arm is locked.

Furthermore, taking the using direction of the flat panel display as reference, the supporting arm system further comprises an adjustable spring base, which comprises two wedge blocks provided at the front portion of the supporting arm; and an adjustable bolt, wherein two wedge blocks have two slop fitting with each other respectively, and the adjustable bolt is adjustably screwed into the two wedge blocks, while the fixed end of the spring is fixed on the adjustable spring base. A main purpose of the adjustable spring base is to make the flat panel display move smart. With adjustment of an assembly length of two wedge blocks by adjusting the adjustable bolt, it could adjust the pretightening force of the spring to meet various flat panel displays with different weights.

Furthermore, taking the using direction of the flat panel display as reference, the supporting arm system further comprises a wiring cover which is fixedly covered outside the supporting arm system, wherein the wiring cover has a plurality of wiring ducts for locating wires therein. Therefore, the power wire and the signal wire of the flat panel display are respectively located in the wiring ducts so as to avoid damage when the flat panel display changing its angle with the desktop, at the same time, to make a more beautiful appearance of the present invention.

Furthermore, the universal head system comprises a universal head, a fixing shaft, and a connecting plate for connecting and fixing the flat panel display. Taking the using direction of the flat panel display as reference, the universal head has an upper flange and a lower flange provided at an rear portion thereof, wherein the upper flange has an oblate hole in the center thereof, and the lower flange has a gradient-diameter hole in the center thereof, wherein the gradient-diameter hole has an axial line coaxially with an axial line of the oblate hole, and has an oblate upper portion and a round lower portion, wherein the oblate hole of the upper flange is larger than the oblate upper portion of the gradient-diameter hole. The hollow column of the connecting head is located between the upper flange and the lower flange. The fixing shaft has a round top end and an oblate bottom end matched to the oblate upper portion of the gradient-diameter hole. Both the round top end and the oblate bottom end of the fixing shaft have an internal thread hole therein, and the fixing shaft is passed through in the hollow column of the connecting head, concretely, the round top end of the fixing shaft protrudes from the hollow column of the connecting head and inserts into the oblate hole of the upper flange. The universal head further comprises an oblate pressing block matched with the oblate hole of the upper flange, having a round hole therein; and a first fastening bolt having external threads thereon matching with the internal thread hole of the round top end of the fixing shaft, wherein the oblate pressing block presses on the round top end of the fixing shaft, and the first fastening bolt passes through the round hole of the oblate pressing block into the internal thread hole of the round top end of the fixing shaft and screws with its threads, wherein one capped end of the first fastening bolt blocks one top end of the oblate pressing block. The universal head further comprises a second fastening bolt having external threads thereon matching with the internal thread hole of the oblate bottom end of the fixing shaft, wherein the oblate bottom end of the fixing shaft is inserted into the oblate upper portion of the gradient-diameter hole, and the second fastening bolt passes through the oblate upper portion of the gradient-diameter hole into the internal thread hole of the oblate bottom end of the fixing shaft and screws with its threads, wherein one capped end of the second fastening bolt is larger than the oblate upper portion of the gradient-diameter hole and smaller than the round lower portion of the gradient-diameter hole so as to located within the gradient-diameter hole. The universal head comprises a plurality of ring friction linings respectively provided between a bottom end surface of the oblate pressing block which located in the upper flange and a top portion of the hollow column of the connecting head, and between the lower flange and a bottom portion of the hollow column of the connecting head. The structure of the universal head and the connecting head as recited above allows the flat panel display installed thereon to turn left and turn right according to different needs. Concretely, an appropriate friction force can be obtained by adjusting a screwing moment of the first fastening bolt so as to make the flat panel display turn left and right freely. Owing to the fixing shaft having the oblate bottom end and the round top end thereof connected an oblate pressing block, the fixing shaft itself does not rotate with turning of the universal head, and the first fastening bolt and the second fastening bolt do not rotate with turning of the universal head either, that is, the friction moment remains constant.

Furthermore, taking the using direction of the flat panel display as reference, the universal head has a spherical concave provided at the front portion thereof, wherein the spherical concave has a square hole positioned in the center thereof communicating the front portion with the rear portion of the universal head. Correspondingly, the connecting plate has a spherical convex provided at the middle portion thereof matching with the spherical concave of the universal head; and a center hole provided in the center of the spherical convex. The universal head system 2 comprises a square-rod fastening bolt having a capped end, a square-rod middle portion, and a threaded end; and a fastening nut matching with the square-rod fastening bolt, wherein the square middle portion is matched with the square hole of the spherical concave. The threaded end of the square-rod fastening bolt is passed through the center hole of the connecting plate and the square hole of the universal head from front to back, and engaged with the fastening nut, wherein the square-rod middle portion of the square-rod fastening bolt is located within the center hole of the connecting plate and the square hole of the universal head, and the capped end of the square-rod fastening bolt is blocked by an rear portion of the connecting plate. The connecting plate comprises a plurality of spherical friction linings respectively provided between the connecting plate and the universal head, and the connecting plate and the capped end of the square-rod fastening bolt, wherein each spherical friction lining has a square frictional hole in the center thereof matching with the square-rod middle portion of the square-rod fastening bolt. The connection structure between the universal head and the connecting plate as recited above allows the flat panel display installed thereon, according to different needs, to adjust its elevation angle and left/right angle, even its vertical angle, that is, a satisfactory friction force can be obtained by adjusting a fastening moment of the square-rod fastening bolt. Owing to fixed by the square hole of the universal head, the square fastening bolt itself does not rotate with the motion of the universal head. Therefore, the friction remains constant for a long enough time so as to make the usage of the flat panel display conveniently.

Furthermore, taking the using direction of the flat panel display as reference, the universal head has a groove extended inwardly from the top portion and the rear portion thereof, wherein the groove has an internal thread hole positioned at a bottom thereof. The universal head system further comprises an arc locking block having a threaded hole therein, and an arc front portion matching with the spherical convex of the connecting plate; and a locking bolt engaged with the threaded hole of the locking block. After the flat panel display adjusted at an appropriate position, dispose the arc locking block in the groove of the universal head, then a capped end of the locking bolt is respectively screwed into the threaded hole of the locking block and the internal thread hole of the groove, and the arc front portion of the locking block is blocked by the connecting plate tightly. The purpose of the structure as recited above is using the locking bolt to adjust the locking block downwardly after the flat panel display adjusted at the appropriate position. That is, due to its arc front portion, the locking block is blocked by the connecting plate during its downward motion, so that the flat panel display is not moved at random.

Taking the using direction of the flat panel display as reference, the universal head further has a first curved slot provided at a rear surface of the spherical concave; and a column projection, matching with the first curved slot, provided at the spherical friction linings between the universal head and the connecting plate, wherein the column projection is embedded into the first curved slot, and slidably moved within the first curved slot. Due to the first curved slot having a certain angle, the rotation angle of the connecting plate relative to its center is limited within a suitable range. Furthermore, the connecting head has a second curved slot provided at the lower portion of the hollow column, and the universal head has a corresponding positioned pin provided at a corresponding part thereof, wherein the positioned pin is embedded into the second curved slot, and slidably moved within the second curved slot. Due to the second curved slot having a certain angle, the left/right angle of the universal head relative to the connecting head is limited within a suitable range.

Preferably, the connecting plate is X-shaped.

Therefore, the universal flat panel display frame of the present invention applies a translation mechanism with dual connecting rod supported by a spring force, and a crosshead universal head system, so as to allow the flat panel display installed thereon to be adjusted and fixed at a desired position and a desired angle randomly.

These and other objectives, features, and advantages of the present invention will become apparent from the following detailed description, the accompanying drawings, and the appended claims.

### BRIEF DESCRIPTION OF THE DRAWINGS

FIG. 1 is a schematic view of a universal flat panel display frame according to a preferred embodiment of the present invention.

FIG. 2 is a structural view of the universal flat panel display frame according to a preferred embodiment of the present invention.

FIG. 3 is a schematic view of a supporting arm system according to a preferred embodiment of the present invention.

FIG. 4 is a schematic view of a universal head system according to a preferred embodiment of the present invention.

FIG. 5 is a schematic view of a universal head system according to the preferred embodiment of the present invention.

FIG. 6 is a schematic view which shows a dead-point position of a linkage mechanism constructed by supporting base, connecting bars, and supporting arm according to the preferred embodiment of the present invention.

### DETAILED DESCRIPTION OF THE PREFERRED EMBODIMENT

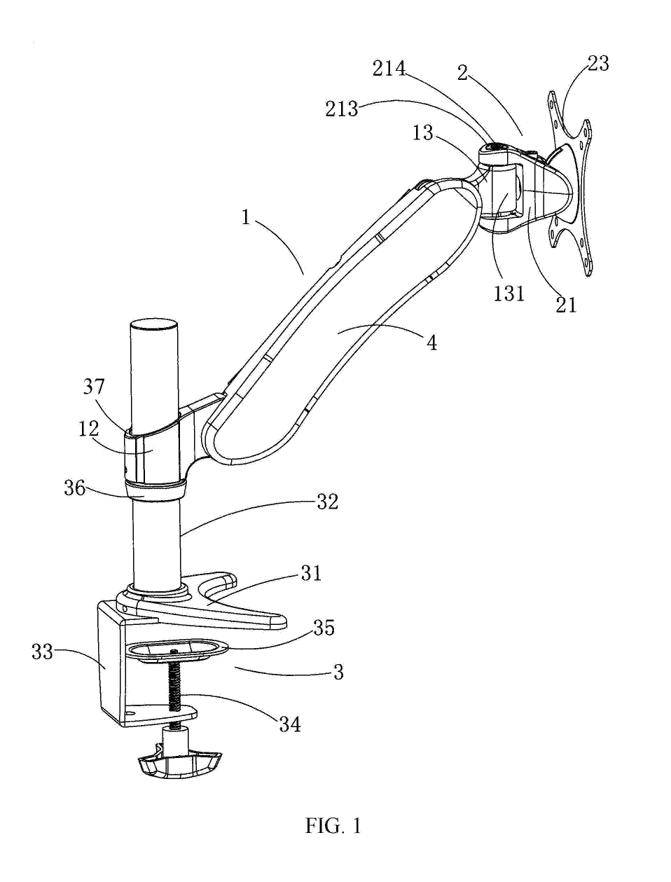

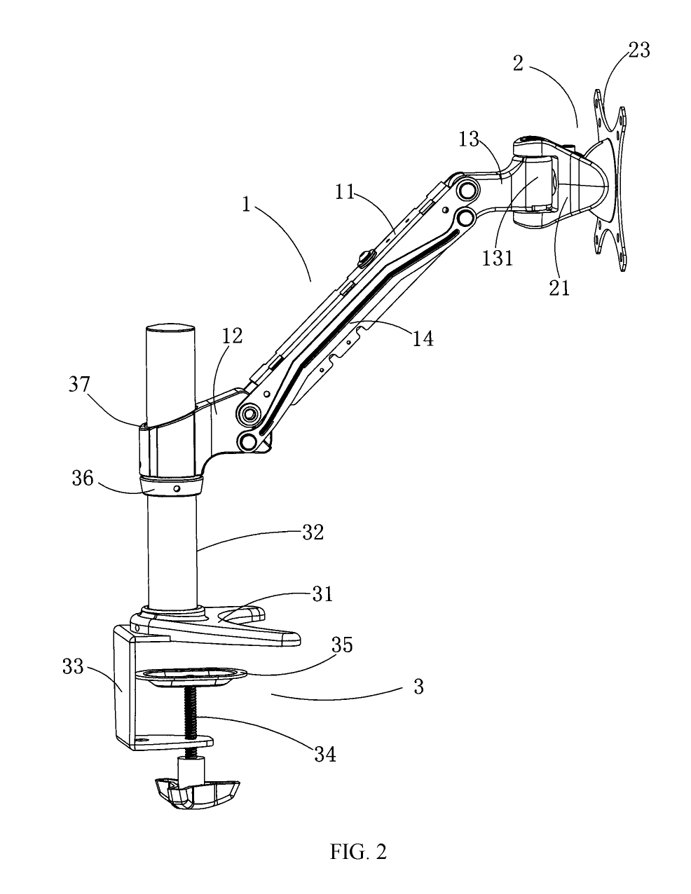

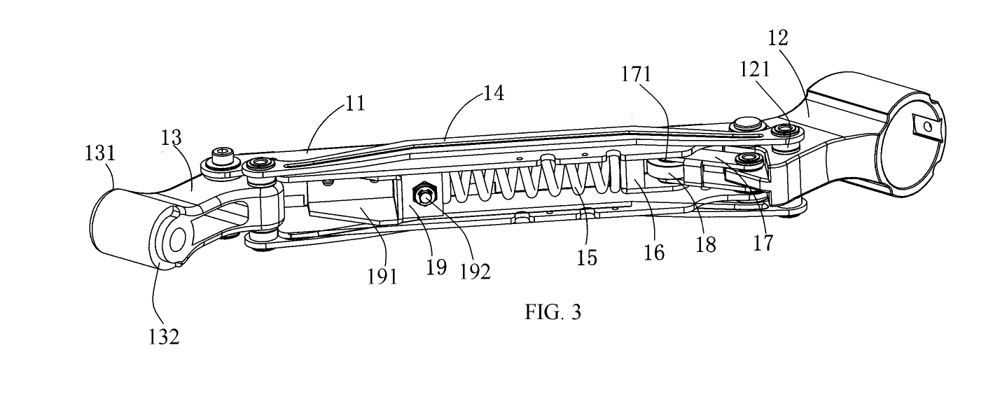

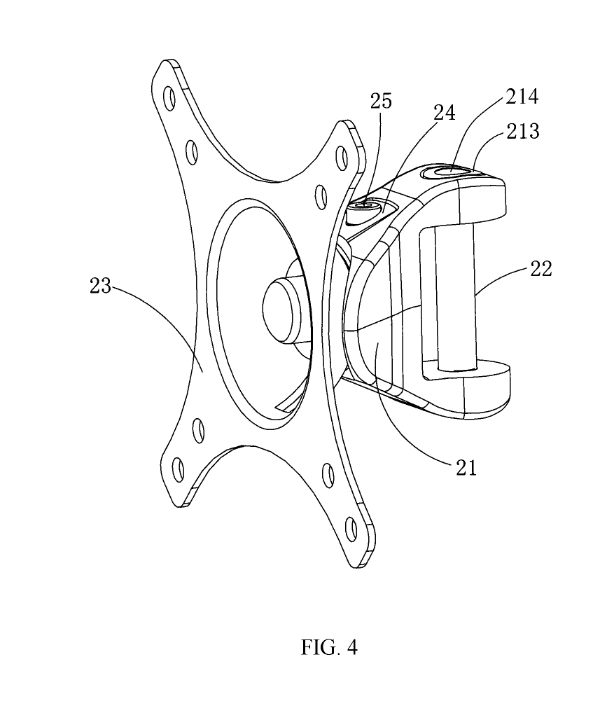

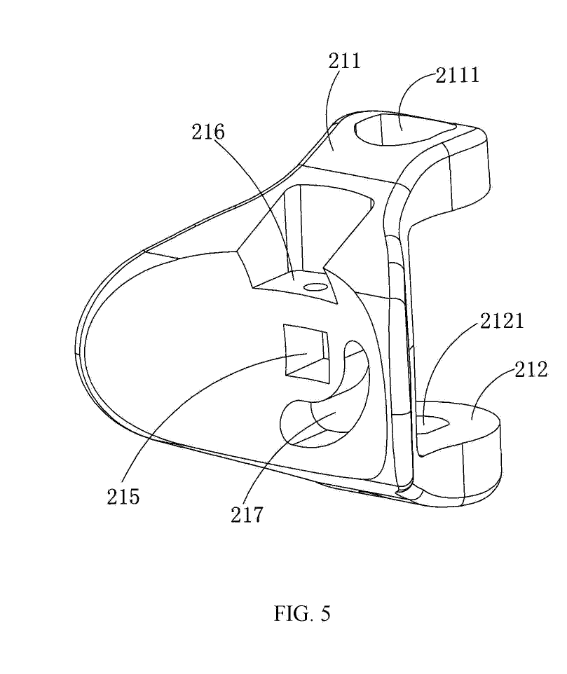

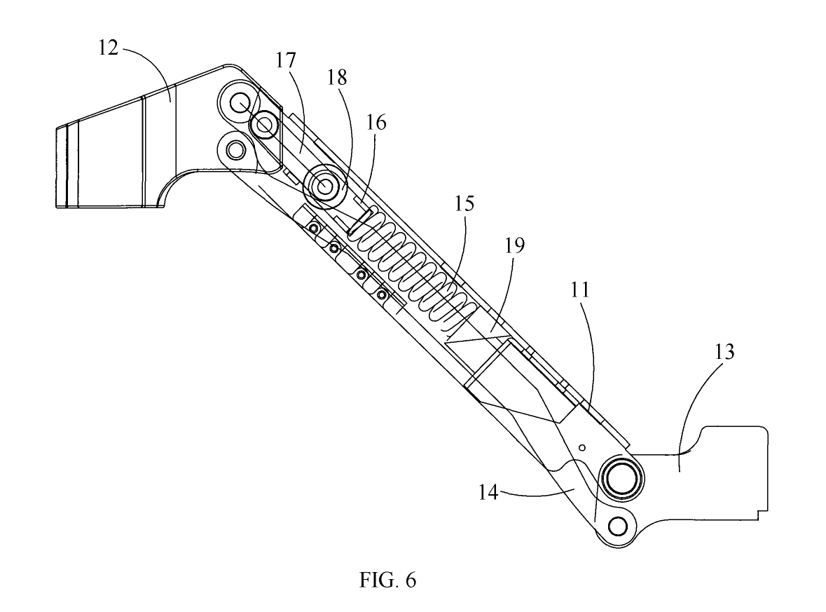

Referring to FIG. 1-FIG. 6 of the drawings, a universal flat panel display frame according to a preferred embodiment of the present invention is illustrated, wherein the universal flat panel display frame comprises a supporting arm system 1, a universal head system 2 and a fixing pedestal system 3. Taking the using direction of the flat panel display as reference, the fixing pedestal system 3 comprises a supporter 31, a column 32, a U-plate 33, a tightening bolt 34, a tightening cover 35, a locating sleeve 36 and a rotating tapered sleeve, wherein the column 32 is fixed on the supporter 31, the U-plate 33 clamps an edge of an desktop, and the supporter 31 is fixed on the U-plate 33. The U-plate 33 has an internal thread hole provided in a bottom thereof, having threads engaged with threads of the tightening bolt 34. A top threaded end of the tightening bolt 34 is screwed through the internal thread hole which provided in the bottom of the U-plate 33, and the tightening cover 35 is fixed on the top threaded end of the tightening bolt 34, while a top surface of the tightening cover 35 is pressed upwardly against a lower surface of the edge of the desktop tightly.

The supporting arm system 1 comprises a supporting arm 11, a supporting base 12, and a connecting head 13. The locating sleeve 36 is sleeved on the column 32, which is fixed by a screw when adjusted to a desired height on the column 32. The rotating tapered sleeve is sleeved on the column 32 coaxially with the locating sleeve 36, and a bottom of the rotating tapered sleeve is pressed against a top of the locating sleeve 36. The supporting base 12 is fixedly sleeved on the rotating sleeved, and hinged with one end of the supporting arm 11. Due to the special connection between the supporting arm system 1 and the fixing pedestal system 3, the supporting arm system 1 is allowed to rotate 360 degree around the column 32 and adjust for height within an entire length of the column 32. That is, the flat panel display fixed on the supporter 31 is allowed to rotate 360 degree around the column 32 and adjust height within an entire length of the column 32.

Another end of the supporting arm 11 is hinged with the connecting head 13, wherein the connecting head 13 has a hollow cylinder 131 in vertical direction, and the universal head system 2 is rotatably connected to the hollow cylinder 131 of the connecting head 13. The supporting arm system 1 further comprises two translation rods 14 symmetrically provided at a left side and a right side of the supporting arm 11, wherein two ends of each translation rod 14 are respectively hinged with the supporting base 12 and the connecting head 13, therefore, the supporting arm 11 and the translation connecting rods 14 between the supporting base 12 and the connecting head 13 constitute two parallel parallelograms so as to form a translation mechanism with dual connecting rod. Whereby, whether the connecting head 13 is moved up or down, an axial lead of its hollow cylinder 131 always parallels to an axial lead of the supporting base 12. Also, because the supporting base 12 is sleeved on the column 32 of the fixing pedestal system 3, while the column 32 is perpendicular to the desktop, and thus the axial lead of its hollow cylinder 131 is always perpendicular to the desktop. That is to say, whether the connecting head is moved up or down, the axial lead of its hollow cylinder 131 is always perpendicular to the desktop.

Taking the using direction of the flat panel display as reference, the supporting arm system 1 further comprises a spring 15 provided inside the supporting arm 11, wherein a fixed end of the spring 15 is mounted on a front portion of the supporting arm 11, and a free end of the spring 15 is fixed on a sliding spring base 16; two connecting bars 17, wherein one end of each connecting bar 17 is hinged with the supporting base 12, and another end of each connecting bar 17 hinged with the sliding spring base 16 by a cylinder pin; a roller 18, with a diameter larger than the width of the sliding spring base 16, sleeved on the cylinder pin for helping the sliding spring base 16 to slide. The supporting base 12, the connecting bars 17 and the supporting arm 11 construct a linkage mechanism, in order to avoid the supporting arm 11 moving down under a moment of force generated by its own gravity and the gravity of the flat panel display.

When the connecting head 13 moves down to cause a larger angle between the supporting arm 11 and the column 32, a gravity center of the supporting arm 11 and the flat panel display shifts outwards, that is, an distance between the force point and the supporting point is increased, the moment of force become larger. Meanwhile, the downward movement of the supporting arm 11 makes the roller 18, mounted on the cylinder pin which connects the sliding spring base 16 to the connecting bars 17, pressed down. Also, due to the one end of the connecting bar 17 hinging with the supporting base 12, the connecting bar 17 can only push the sliding spring base 16 to move toward the compression direction of the spring 15, and with movement of the sliding spring base 16, an elastic force of the spring 15 become larger, therefore, a countermoment of the elastic force is enough to balance the moment of force generated by its own gravity and the gravity of the flat panel display, so as to keep the flat panel display still in balance. When the supporting arm 11 is moved in a horizontal position, the distance between the flat panel display and a user is smallest. Continuing to move the supporting arm 11 down, under a push action of the connecting bars 17 on the spring 15, the spring 15 is further compressed to a status that the connecting points between the supporting base 12 and the supporting arm 11, the connecting points between the connecting bars 17 and the supporting base 12, and the connecting points between the connecting bars 17 and the sliding spring base 18 are in a line, then the linkage mechanism constructed by the supporting base 12, the connecting bars 17, and the supporting arm 11 is in a dead-point position, and the elastic force of the spring 15 reaches to maximum value at this position.

According to the preferred embodiment of the present invention, the supporting arm system 1 further comprises two locating loops respectively sleeved on two connecting points between the supporting base 12 and the connecting bars 17 for forming a lock mechanism, wherein when the linkage mechanism passes its dead-point position, one side of the supporting arm 11 is blocked by the locating loops so as to avoid the flat panel display is elevated by the excessive elastic force of the spring 15. Concretely speaking, when the supporting arm 11 is moved slightly down after the linkage mechanism reaching its dead-point position, the linkage mechanism will pass its dead-point position, then the side of the supporting arm 11 is blocked by the locating loops for avoiding further falling, that is, the supporting arm 11 is locked.

Taking the using direction of the flat panel display as reference, the supporting arm system 1 further comprises an adjustable spring base 19, which comprises two wedge blocks provided at the front portion of the supporting arm 11; and an adjustable bolt, wherein two wedge blocks have two slop fitting with each other respectively, and the adjustable bolt is adjustably screwed into the two wedge blocks, while the fixed end of the spring 15 is fixed on the adjustable spring base 19. A main purpose of the adjustable spring base 19 is to make the flat panel display move smart. With adjustment of an assembly length of two wedge blocks by adjusting the adjustable bolt, it could adjust the pretightening force of the spring 15 to meet various flat panel displays with different weights.

Furthermore, taking the using direction of the flat panel display as reference, the supporting arm system 1 further comprises a wiring cover 4 which is fixedly covered outside the supporting arm system 1, wherein the wiring cover 4 has a plurality of wiring ducts for locating wires therein. Therefore, the power wire and the signal wire of the flat panel display are respectively located in the wiring ducts so as to avoid damage when the flat panel display changing its angle with the desktop, at the same time, to make a more beautiful appearance of the present invention.

The universal head system 2 comprises a universal head 21, a fixing shaft 22, and a connecting plate 23 for connecting and fixing the flat panel display. Taking the using direction of the flat panel display as reference, the universal head 21 has an upper flange 211 and a lower flange 212 provided at an rear portion thereof, wherein the lower flange 212 is provided beneath the upper flange 211, wherein the upper flange 211 has an oblate hole 2111 in the center thereof, and the lower flange 212 has a gradient-diameter hole 2121 in the center thereof, wherein the gradient-diameter hole 2121 has an axial line coaxially with an axial line of the oblate hole 2111, and has an oblate upper portion and a round lower portion, wherein the oblate hole 2111 of the upper flange 211 is larger than the oblate upper portion of the gradient-diameter hole 2121. The hollow column 131 of the connecting head 13 is located between the upper flange 211 and the lower flange 212. The fixing shaft 22 has a round top end and an oblate bottom end matched to the oblate upper portion of the gradient-diameter hole 2121. Both the round top end and the oblate bottom end of the fixing shaft 22 have an internal thread hole therein, and the fixing shaft 22 is passed through the hollow column 131 of the connecting head 13, concretely, the round top end of the fixing shaft 22 protrudes from the hollow column 131 of the connecting head 13 and inserts into the oblate hole 2111 of the upper flange 211. The universal head 21 further comprises an oblate pressing block 213 matched with the oblate hole 2111 of the upper flange 211, having a round hole therein; and a first fastening bolt 214 having external thread thereon matching with the internal thread hole of the round top end of the fixing shaft 22, wherein the oblate pressing block 213 presses on the round top end of the fixing shaft 22, and the first fastening bolt 214 passes through the round hole of the oblate pressing block 213 into the internal thread hole of the round top end of the fixing shaft 22 and screws with its threads, wherein one capped end of the first fastening bolt 214 blocks one top end of the oblate pressing block 213. The universal head 21 further comprises a second fastening bolt having external threads thereon matching with the internal thread hole of the oblate bottom end of the fixing shaft 22, wherein the oblate bottom end of the fixing shaft 22 is inserted into the oblate upper portion of the gradient-diameter hole 2121, and the second fastening bolt passes through the oblate upper portion of the gradient-diameter hole 2121 into the internal thread hole of the oblate bottom end of the fixing shaft 22 and screws with its threads, wherein one capped end of the second fastening bolt is larger than the oblate upper portion of the gradient-diameter hole 2121 and smaller than the round lower portion of the gradient-diameter hole 2121 so as to located within the gradient-diameter hole 2121.

Furthermore, the universal head 21 comprises a plurality of ring friction linings respectively provided between a bottom end surface of the oblate pressing block 213 which located in the upper flange 211 and a top portion of the hollow column 131 of the connecting head 13, and between the lower flange 212 and a bottom portion of the hollow column 131 of the connecting head 13.

The structure of the universal head 21 and the connecting head 13 as recited above allows the flat panel display installed thereon to turn left and turn right according to different needs. Concretely, an appropriate friction force can be obtained by adjusting a screwing moment of the first fastening bolt 214 so as to make the flat panel display turn left and right freely. Owing to the fixing shaft 22 having the oblate bottom end and the round top end thereof connected an oblate pressing block 213, the fixing shaft 22 itself does not rotate with turning of the universal head 21, and the first fastening bolt 214 and the second fastening bolt do not rotate with turning of the universal head 21 either, that is, the friction moment remains constant.

Taking the using direction of the flat panel display as reference, the universal head 21 has a spherical concave provided at the front portion thereof, wherein the spherical concave has a square hole 215 positioned in the center thereof communicating the front portion with the rear portion of the universal head 21. Correspondingly, the connecting plate 23 has a spherical convex provided at the middle portion thereof matching with the spherical concave of the universal head 21; and a center hole provided in the center of the spherical convex. The universal head system 2 further comprises a square-rod fastening bolt having a capped end, a square-rod middle portion, and a threaded end; and a fastening nut matching with the square-rod fastening bolt, wherein the square middle portion is matched with the square hole 215 of the spherical concave. The threaded end of the square-rod fastening bolt is passed through the center hole of the connecting plate 23 and the square hole 215 of the universal head 21 from front to back, and engaged with the fastening nut, wherein the square-rod middle portion of the square-rod fastening bolt is located within the center hole of the connecting plate 23 and the square hole 215 of the universal head 21, and the capped end of the square-rod fastening bolt is blocked by an rear portion of the connecting plate 23. Furthermore, the connecting plate 23 comprises a plurality of spherical friction linings respectively provided between the connecting plate 23 and the universal head 21, and the connecting plate 23 and the capped end of the square-rod fastening bolt, wherein each spherical friction lining has a square frictional hole in the center thereof matching with the square-rod middle portion of the square-rod fastening bolt.

The connection structure between the universal head 21 and the connecting plate 23 as recited above allows the flat panel display installed thereon, according to different needs, to adjust its elevation angle and left/right angle, even its vertical angle. Concretely, a satisfactory friction force can be obtained by adjusting a fastening moment of the square-rod fastening bolt. Owing to fixed by the square hole 215 of the universal head, the square fastening bolt itself does not rotate with the motion of the universal head 2. Therefore, the friction remains constant for a long enough time so as to make the usage of the flat panel display conveniently.

Taking the using direction of the flat panel display as reference, furthermore, the universal head 21 has a groove 216 extended inwardly from the top portion and the rear portion thereof, wherein the groove 216 has an internal thread hole positioned at a bottom thereof. The universal head system 2 further comprises an arc locking block 24 having a threaded hole therein, and an arc front portion matching with the spherical convex of the connecting plate 23; and a locking bolt 25 engaged with the threaded hole of the locking block 24. After the flat panel display adjusted at an appropriate position, dispose the arc locking block 24 in the groove 216 of the universal head 21, then a capped end of the locking bolt 25 is respectively screwed into the threaded hole of the locking block 24 and the internal thread hole of the groove 216, and the arc front portion of the locking block 24 is blocked by the connecting plate 23 tightly. The purpose of the structure as recited above is using the locking bolt 25 to adjust the locking block 24 downwardly after the flat panel display adjusted at the appropriate position. That is, due to its arc front portion, the locking block 24 is blocked by the connecting plate 23 during its downward motion, so that the flat panel display is not moved at random.

Taking the using direction of the flat panel display as reference, the universal head 21 further has a first curved slot 217 provided at a rear surface of the spherical concave; and a column projection, matching with the first curved slot 217, provided at the spherical friction linings between the universal head 21 and the connecting plate 23, wherein the column projection is embedded into the first curved slot 217, and slidably moved within the first curved slot 217. Due to the first curved slot 217 having a certain angle, the rotation angle of the connecting plate 23 relative to its center is limited within a suitable range. Furthermore, the connecting head 13 has a second curved slot provided at the lower portion of the hollow column 131, and the universal head 21 has a corresponding positioned pin provided at a corresponding part thereof, wherein the positioned pin is embedded into the second curved slot, and slidably moved within the second curved slot. Due to the second curved slot having a certain angle, the left/right angle of the universal head 21 relative to the connecting head 13 is limited within a suitable range.

According to the preferred embodiment of the present invention, the connecting plate 23 is X-shaped.

The universal flat panel display frame provided by the present invention allows the flat panel display installed thereon to be adjustable within the following ranges:
(1) the flat panel display allowed to rotate 360 degree around the column 32;
(2) the flat panel display allowed to move from 181.1 mm upward to 137.2 mm downward;
(3) the flat panel display allowed to incline from 30 degree forward to 30 degree backward;
(4) the flat panel display allowed to incline from 50 degree leftward to 50 degree rightward.

Only one person could activate the flat panel display by hand. The height, front/back incline angle and right/left incline angle of the flat panel display can be adjusted at random just by applying a little force. Therefore, the flat panel display installed on the universal flat panel display frame provided by the present invention is convenient for a user to adjust the flat panel at a desired position, or to rotate the flat panel display at a desired angle to show the screen to other people.

An installation process of the universal flat panel display frame provided by the present invention is as follows:

(a) clamping the edge of the desktop by the U-plate 33 of the fixing pedestal system 3;

(b) choosing a desired installing position;

(c) screwing the tightening bolt 34 by hand to press the top surface of the tightening cover 35 upwardly against the lower surface of the edge of the desktop tightly;

(d) mounting the supporting base 12 sleevedly on the rotating tapered sleeve;

(e) installing the flat panel display on the connecting plate 23 which is formed X-shaped by blot;

(f) adjusting the elastic force of the spring 15 to balance the gravity of the flat panel display so as to keep the flat panel display balance in free state;

(g) adjusting the front/back incline angle and the right/left incline angle of the flat panel display to obtain an comfortable position;

(h) fixing the flat panel display at the comfortable position.

It is worth to mention that the present invention can be applied to wall set type or suspended type after modifying the installation of the fixing pedestal system 3. For example, the universal flat panel display frame provided by the present invention can be a wall set frame for the flat panel display only by modifying the supporter 31 of the fixing pedestal system 3 to a wall set supporter.

One skilled in the art will understand that the embodiment of the present invention as shown in the drawings and described above is exemplary only and not intended to be limiting.

It will thus be seen that the objects of the present invention have been fully and effectively accomplished. Its embodiments have been shown and described for the purposes of illustrating the functional and structural principles of the present invention and is subject to change without departure from such principles. Therefore, this invention includes all modifications encompassed within the spirit and scope of the following claims.

1-10. (canceled)

11. A universal flat panel display frame, comprising:
a fixing pedestal system, which comprises a supporter supporting said universal flat panel display frame on a desktop; a column fixed on said supporter; a locating sleeve sleeved on said column and fixed after being adjusted to a desired height; and a rotating tapered sleeve sleeved on said column coaxially with said locating sleeve, wherein a bottom of said rotating tapered is pressed against a top of said locating sleeve;
a supporting arm system, which comprises
a supporting base fixedly sleeved on said rotating sleeve;
a connecting head, having a hollow cylinder provided in a vertical direction thereof;
a supporting arm, wherein one end of said supporting arm is hinged with said supporting base, another end of said supporting arm is hinged with said connecting head; and
two translation rods symmetrically provided at a left side and a fight side of said supporting arm, wherein two ends of each translation rod are respectively hinged with said supporting base and said connecting head, wherein said supporting arm and said translation connecting rods hinged between said supporting base and said connecting head constitute two parallel parallelograms so as to form a translation mechanism with dual connecting rod; and
a universal head system rotatably connected to said hollow cylinder of said connecting head, wherein the flat panel display is installed thereon.

12. The universal flat panel display frame, as recited in claim 11, wherein said fixing pedestal system further comprises:
a U-plate clamping an edge of the desktop, having an internal thread hole provided in a bottom thereof, wherein said supporter is fixed on said U-plate;
a tightening bolt matching with said internal thread hole, wherein a top threaded end of said tightening bolt is screwed through said internal thread hole; and
a tightening cover fixed on the top threaded end of the tightening bolt, wherein a top surface of said tightening cover is pressed upwardly against a lower surface of the edge of the desktop tightly.

13. The universal flat panel display frame, as recited in claim 12, wherein the supporting arm system further comprises:
a spring provided inside said supporting arm, having a fixed end and a free end, wherein said fixed end is mounted on a front portion of said supporting arm;
a sliding spring base, wherein said free end of said spring is fixed on said sliding spring base;
a cylinder pin;
two connecting bars, wherein one end of each connecting bar is hinged with said supporting base forming a connecting point, and another end of each connecting bar hinged with said sliding spring base by said cylinder pin; and
a roller sleeved on said sliding spring base for helping said sliding spring base to slide, wherein said supporting base, said connecting bars and said supporting arm construct a linkage mechanism, so as to avoid said supporting arm moving down under a moment of force generated by its own gravity and the gravity of the flat panel display.

14. The universal flat panel display frame, as recited in claim 13, wherein said supporting arm system further comprises two locating loops respectively sleeved on said connecting points between said supporting base and said connecting bars for forming a lock mechanism.

15. The universal flat panel display frame, as recited in claim 14, wherein said supporting arm system further comprises an adjustable spring base, fixing said fixed end of said spring thereon, which comprises two wedge blocks provided at said front portion of said supporting arm; and an adjustable bolt, wherein said two wedge blocks fit each other, and said adjustable bolt is adjustably screwed into said two wedge blocks, wherein said fixed end of said spring is fixed on said adjustable spring base.

16. The universal flat panel display frame, as recited in claim 1, wherein said supporting arm system further comprises a wiring cover fixedly covered outside said supporting arm system, having a plurality of wiring ducts for locating wires of the plat panel display therein.

17. The universal flat panel display frame, as recited in claim 15, wherein said supporting arm system further comprises a wiring cover fixedly covered outside said supporting arm system, having a plurality of wiring ducts for locating wires of the plat panel display therein.

18. The universal flat panel display frame, as recited in claim 1, wherein said universal head system comprises:
a fixing shaft passing through said hollow cylinder of said connecting head, having a round top end with an internal thread hole therein and an oblate bottom end with an internal thread hole therein;
a universal head, having:
a upper flange provided at an rear portion thereof, having an oblate hole in a center of said upper flange; and
a lower flange provided at an rear portion thereof and beneath said upper flange, having a gradient-diameter hole in a center of said lower flange, wherein said gradient-diameter hole has an axial line coaxially with an axial line of said oblate hole, and has an oblate upper portion and a round lower portion, wherein said oblate hole of said upper flange is larger than said oblate upper portion of said gradient-diameter hole, wherein said hollow column of said connecting head is located between said upper flange and said lower flange; and comprising:
an oblate pressing block matched with said oblate hole of said upper flange, having a round hole in said oblate pressing block; and
a first fastening bolt having external thread thereon matching with said internal thread hole of said round top end of said fixing shaft, wherein said round top end of said fixing shaft protrudes from said hollow column of said connecting head and inserts into said oblate hole of said upper flange, said oblate pressing block presses on said round top end of said fixing shaft, and said first fastening bolt passes through said round hole of said oblate pressing block into said internal thread hole of said round top end of said fixing shaft and screws with its threads, wherein one capped end of said first fastening bolt blocks one top end of said oblate pressing block; and
a connecting plate connected to said universal head, wherein the flat panel display is installed on said connecting plate.

19. The universal flat panel display frame, as recited in claim 17, wherein said universal head system comprises:
a fixing shaft passing through said hollow cylinder of said connecting head, having a round top end with an internal thread hole therein and an oblate bottom end with an internal thread hole therein;
a universal head, having:
a upper flange provided at an rear portion thereof, having an oblate hole in a center of said upper flange; and
a lower flange provided at an rear portion thereof and beneath said upper flange, having a gradient-diameter hole in a center of said lower flange, wherein said gradient-diameter hole has an axial line coaxially with an axial line of said oblate hole, and has an oblate upper portion and a round lower portion, wherein said oblate hole of said upper flange is larger than said oblate upper portion of said gradient-diameter hole, wherein said hollow column of said connecting head is located between said upper flange and said lower flange; and comprising:
an oblate pressing block matched with said oblate hole of said upper flange, having a round hole in said oblate pressing block; and
a first fastening bolt having external thread thereon matching with said internal thread hole of said round top end of said fixing shaft, wherein said round top end of said fixing shaft protrudes from said hollow column of said connecting head and inserts into said oblate hole of said upper flange, said oblate pressing block presses on said round top end of said fixing shaft, and said first fastening bolt passes through said round hole of said oblate pressing block into said internal thread hole of said round top end of said fixing shaft and screws with its threads, wherein one capped end of said first fastening bolt blocks one top end of said oblate pressing block; and
a connecting plate connected to said universal head, wherein the flat panel display is installed on said connecting plate.

20. The universal flat panel display frame, as recited in claim 19, wherein said universal head further comprises a second fastening bolt having external thread thereon matching with said internal thread hole of said oblate bottom end of said fixing shaft, wherein said oblate bottom end of said fixing shaft is inserted into said oblate upper portion of said gradient-diameter hole, and said second fastening bolt passes through said oblate upper portion of said gradient-diameter hole into said internal thread hole of said oblate bottom end of said fixing shaft and screws with its threads, wherein one capped end of said second fastening bolt is larger than said oblate upper portion of said gradient-diameter hole and smaller than said round lower portion of said gradient-diameter hole so as to located within said gradient-diameter hole.

21. The universal flat panel display frame, as recited in claim 20, wherein said universal head further comprises a plurality of ring friction linings respectively provided between a bottom end surface of said oblate pressing block and a top portion of said hollow column of said connecting head, and between said lower flange and a bottom portion of said hollow column of said connecting head.

22. The universal flat panel display frame, as recited in claim 20, wherein said universal head has a spherical concave provided at a front portion thereof, wherein said spherical concave has a square hole positioned in a center thereof communicating said front portion with said rear portion of said universal head;
wherein said connecting plat has a spherical convex provided at a middle portion thereof matching with said spherical concave of said universal head; and a center hole provided in a center of said spherical convex;
wherein said universal head system further comprises a square-rod fastening bolt having a capped end, a square-rod middle portion, and a threaded end; and a fastening nut matching with said square-rod fastening bolt, wherein said square middle portion is matched with said square hole of said spherical concave, wherein said threaded end of said square-rod fastening bolt is passed through said center hole of said connecting plate and said square hole of said universal head from front to back, and engaged with said fastening nut, wherein said square-rod middle portion of said square-rod fastening bolt is located within said center hole of said connecting plate and said square hole of said universal head, and said capped end of said square-rod fastening bolt is blocked by an rear portion of said connecting plate.

23. The universal flat panel display frame, as recited in claim 21, wherein said universal head has a spherical concave provided at a front portion thereof, wherein said spherical concave has a square hole positioned in a center thereof communicating said front portion with said rear portion of said universal head;
wherein said connecting plat has a spherical convex provided at a middle portion thereof matching with said spherical concave of said universal head; and a center hole provided in a center of said spherical convex;
wherein said universal head system further comprises a square-rod fastening bolt having a capped end, a square-rod middle portion, and a threaded end; and a fastening nut matching with said square-rod fastening bolt, wherein said square middle portion is matched with said square hole of said spherical concave, wherein said threaded end of said square-rod fastening bolt is passed through said center hole of said connecting plate and said square hole of said universal head from front to back, and engaged with said fastening nut, wherein said square-rod middle portion of said square-rod fastening bolt is located within said center hole of said connecting plate and said square hole of said universal head, and said capped end of said square-rod fastening bolt is blocked by an rear portion of said connecting plate.

24. The universal flat panel display frame, as recited in claim 23, wherein said connecting plate comprises a plurality of spherical friction linings respectively provided between said connecting plate and said universal head, and said connecting plate and said capped end of said square-rod fastening bolt, wherein each spherical friction lining has a square frictional hole in a center thereof matching with said square-rod middle portion of said square-rod fastening bolt.

25. The universal flat panel display frame, as recited in claim 24, said universal head has a groove extended inwardly from a top portion and said rear portion thereof, wherein said groove has an internal thread hole positioned at a bottom thereof;
wherein said universal head system further comprises an arc locking block having a threaded hole therein, and an arc front portion matching with said spherical convex of said connecting plate; and a locking bolt engaged with said threaded hole of said locking block, wherein after the flat panel display adjusted at an appropriate position, dispose said arc locking block in said groove of said universal head, wherein a capped end of said locking bolt is respectively screwed into said threaded hole of said locking block and said internal thread hole of said groove, and said arc front portion of said locking block is blocked by said connecting plate tightly.

26. The universal flat panel display frame, as recited in claim 24, wherein said universal head further has a first curved slot provided at a rear surface of said spherical concave; and a column projection, matching with said first curved slot, provided at said spherical friction linings between said universal head and said connecting plate, wherein said column projection is embedded into said first curved slot, and slidably moved within said first curved slot.

27. The universal flat panel display frame, as recited in claim 25, wherein said universal head further has a first curved slot provided at a rear surface of said spherical concave; and a column projection, matching with said first curved slot, provided at said spherical friction linings between said universal head and said connecting plate, wherein said column projection is embedded into said first curved slot, and slidably moved within said first curved slot.

28. The universal flat panel display frame, as recited in claim 27, wherein said connecting head has a second curved slot provided at a lower portion of said hollow column, and said universal head has a corresponding positioned pin provided at a corresponding part thereof, wherein said positioned pin is embedded into said second curved slot, and slidably moved within said second curved slot.

29. The universal flat panel display frame, as recited in claim 1, wherein said connecting plate is X-shaped.

30. The universal flat panel display frame, as recited in claim 28, wherein said connecting plate is X-shaped.
